(19) United States
(12) Patent Application Publication
(10) Pub. No.: US 2019/0305205 A1
(43) Pub. Date: Oct. 3, 2019

(54) Power Module Having Reduced Susceptibility to Defects, and Use Thereof

(71) Applicant: TDK Electronics AG, München (DE)

(72) Inventor: Thomas Feichtinger, Graz (AT)

(21) Appl. No.: 16/347,166

(22) PCT Filed: Oct. 23, 2017
(86) PCT No.: PCT/EP2017/077010

§ 371 Date: May 2, 2019

(30) Foreign Application Priority Data
Nov. 16, 2016 (DE) 102016122014.0

(51) Int. Cl. H01L 33/64; H01L 25/16; H05K 1/02; H05K 1/18

(52) U.S. Cl. CPC H01L 33/647; H01L 25/167; H05K 1/0204; H05K 2201/10196; H05K 1/183; H05K 2201/10106; H05K 1/0259

(57) ABSTRACT

A power module is disclosed. In an embodiment a power module includes a carrier substrate having a dielectric layer, a metallization layer and a recess and an electrical functional element, wherein the metallization layer includes a structured electrical conductor, wherein the functional element is interconnected with the electrical conductor, wherein the functional element is arranged in the recess, and wherein the functional element includes a thermal bridge that has a greater thermal conductivity than the carrier substrate.

This patent application is a national phase filing under section 371 of PCT/EP2017/077010, filed Oct. 23, 2017, which claims the priority of German patent application 102016122014.0, filed Nov. 16, 2016, each of which is incorporated herein by reference in its entirety.

### TECHNICAL FIELD

The invention relates to power modules.

### BACKGROUND

Increasingly more electrical and electronic components are being used in technical devices. Correspondingly, there is an increase in their complexity, and thus in the number of possibilities of a defect. In addition, the trend towards miniaturization is continuing, with the result that the structural space for realizing electrical and electronic functions is becoming ever smaller.

Electrical and electronic functions are often realized by electrical modules. A module generally combines a plurality of electrical components, e.g., chips, on a carrier substrate. Such modules are known, for example, from US patent applications publications No. 2009/0129079 A1 and No. 2008/0151547 A1.

In comparison with systems that merely process electrical signals, power modules, e.g., lamps for road lighting (main beam, dipped beam) in motor vehicles, are characterized by high electrical power ratings. Correspondingly, the waste heat is also a multiple of the waste heat of signal-processing modules.

A problem in the case of known power modules is the susceptibility to defects, and a thermal limitation of the performance capability.

### SUMMARY OF THE INVENTION

Embodiments provide power modules having a reduced susceptibility to defects, greater performance stability and greater performance capability.

Various embodiments provide a power module comprising a carrier substrate having a dielectric layer and a metallization layer. The carrier substrate also has a recess. In addition, the power module comprises an electrical functional element. There is an electrical conductor structured in the metallization layer of the carrier substrate. The functional element is interconnected with the electrical conductor. The functional element is additionally arranged in the recess in the carrier substrate, and has a thermal bridge, which has a greater thermal conductivity than the carrier substrate.

The recess in this case may be an opening going through the carrier substrate, such that the recess is accessible from both sides of the carrier substrate. Alternatively, the recess may also be a depression in the form of a blind hole that does not extend through the carrier substrate. The recess is then accessible only from the upper side of the carrier substrate. In the latter case, the recess has an underside, which is formed by a surface of the carrier substrate.

Besides the one dielectric layer and the one metallization layer, the carrier substrate may also have one or more further dielectric layers and one or further metallization layers. The dielectric layers separate the metallization layers. There may be electrical structures, e.g., signal lines, power conductors, circuit elements such as capacitive, inductive or resistive elements, structured in the metallization layers.

The functional element is an electrical or electronic power element that, when in operation, transforms a relatively high electrical power and dissipates a correspondingly large quantity of energy. During operation, therefore, the functional element constitutes a heat source. Possible functional elements are, in particular, elements having structures for high-power LEDs (LED=light-emitting diode).

In addition to the structures that act as a heat source and convert electrical energy partially into heat, the functional element has its heat bridge having the high thermal conductivity. In comparison with conventional power modules having heat sources in chips on a carrier substrate, the material on the carrier substrate through which the heat must be removed is reduced as a result of being arranged in the recess. Owing to the additional presence of the thermal bridge, which further improves the removal of heat as a result of having a greater thermal conductivity than the carrier substrate, the thermal load of the energy-dissipating structures in the functional element is doubly reduced.

The temperature range in which motor vehicles are used is very wide. Daytime running lights, in particular, which are used not only in the rather cooler darkness, and which are generally based on LEDs comprising doped semiconductor material, benefit from an improved heat removal. The ageing of semiconductor components is a thermodynamic process with an exponential dependence on temperature. A significant reduction of the thermal load can therefore multiply the service life of a corresponding component and reduce the susceptibility to defects.

In addition, as a result of the functional element being arranged in the recess, the structural height of the module is reduced.

Paradoxically, the reduction of the susceptibility to defects is thus based precisely on the decrease in the structural volume.

There is thus specified, overall, a power module that is very suitable for high-power power components, e.g., thermally sensitive power semiconductors. The susceptibility to defects is reduced. Temperature fluctuations are reduced because of the generally lower temperature level. Owing to the improved heat removal, the power stability is increased, and a corresponding electrical component can be operated at higher power. The functional element in the recess can be mechanically fixed to the lateral walls of the recess, such that, despite the recess in principle compromising the mechanical stability of the substrate, a mechanically robust module is obtained. The dimensions, in particular the structural height, are reduced. Owing to the possibility of the lesser dimensions, the number of degrees of freedom in the designing of corresponding modules is increased, which in turn leaves space for measures to facilitate the processibility of the modules.

Moreover, it has been identified that the thermal bridge can also be formed such that structures for protecting the module against overvoltages are retained, thereby reducing not only the defect susceptibility in respect of thermally induced defects, but also the defect susceptibility in respect of hazardous electrical pulses.

It is therefore correspondingly possible for the thermal bridge to be designed to remove heat, generated during operation, e.g., dissipated electrical energy, to the underside of the power module.

The power module may be fastened on a mounting plate, via which the generated heat can easily be removed to the environment of the module.

It is possible for the thermal bridge to comprise a ceramic material.

The ceramic material in this case may be a dielectric material, which insulates power structures of the functional element with respect to its environment and nevertheless allows a good thermal coupling to the underside of the power module.

It is possible for the thermal bridge to comprise a material or be composed of the material, the material being selected from ZnO—Bi (bismuth-doped zinc oxide), ZnO—Pr (praseodymium-doped zinc oxide), AlN (an aluminum nitride), Al₂O₃ and SiC (silicon carbide).

The carrier substrate may comprise the usual materials that are used for PCBs (PCB=printed circuit board). The carrier substrate may be, for example, a multilayer FR4 substrate. Alternatively, the carrier substrate may also be an IMS substrate (IMS=insulated metal substrate). The thermal conductivity of known carrier substrates is limited substantially to 8 W/mK or less. Bismuth-doped zinc oxide has a thermal conductivity of 20 W/mK or more. Zinc oxide doped with praseodymium has a thermal conductivity of 40 w/mK or more. Aluminum nitride has a thermal conductivity of 100 W/mK or more. This means that—together with the reduced mass through which heat must be removed—the thermal coupling can be improved by an order of magnitude, or more.

It is possible for the thermal bridge to comprise a multilayer structure. The multilayer structure may have a dielectric layer and a metallization layer. In addition to this dielectric layer, the thermal bridge may have further dielectric layers. In addition to the metallization layer, the thermal bridge may have further metallization layers.

Electrical functions may be realized in the layers of the multilayer structure. Preferably, the dielectric material and the material of the metallization layers are selected such that there is an optimal removal of heat by the entire thermal bridge.

It is possible for the thermal bridge to comprise an ESD protective element (ESD=electrostatic discharge).

The ESD protective element in this case may protect functional structures of the functional element against harmful voltage pulses.

For this purpose, it is possible for the thermal bridge to comprise a varistor.

The thermal bridge may for this purpose comprise a multilayer structure, structured in which there are first electrodes, which are arranged above one another and which are separate from the dielectric material. Structured between the first electrodes, in further metallization layers, are second electrode surfaces that are separate from the first electrodes.

The dielectric material, in the form of a varistor ceramic, in this case has an electrical resistance that is dependent on the voltage present at the electrodes. As a result, unwanted overvoltage pulses can easily be discharged to a protection potential, e.g., a frame potential, while in the case of the usual operating voltages of the functional element the dielectric material constitutes an insulator.

The power module may have, besides the functional element, yet further, additional functional elements, of the same or similar structure, which also may be arranged in the recess or in additional recesses. A high degree of integration is obtained by such an arrangement. The greater the degree of integration, and thus the higher the number of integrated functional elements, the greater is the probability of failure. It would be undesirable if a power module were to be unusable because of the failure of a single functional element. Owing to the possibility of an ESD protection, as described above, a highly integrated component, having a multiplicity of functional elements that transform high power, can thus be obtained, and a probability of failure can nevertheless be reduced to a minimum.

It is possible for the functional element to comprise functional structures that can be excited to emit light.

The functional structures in this case are preferably arranged on the upper side of the functional element, while the thermal bridge thermally couples the functional structures to the underside of the functional element, e.g., to the underside of the power module. Structures that can be excited to emit light may be, in particular, LED structures based on semiconductor material, since such semiconductor structure is particularly sensitive to overheating.

It is possible for the carrier substrate and/or the functional element to have vertical through-platings, so-called vias. Vertical through-platings in this case interconnect differing metallization layers, or the circuit elements structured in the differing metallization layers. Such through-platings enable all electrical connections of the power module to be arranged on a single side, e.g., the underside. Correspondingly, it is also possible for the functional element to have all electrical connections to the carrier substrate on its underside. The functional element is then arranged, in the recess, on one layer of the carrier substrate, and interconnected via structured conductors.

Known IMS substrates, having full-surface metalized layers between dielectric layers, would not allow such a contacting, since correspondingly embodied through-platings in the vertical direction would be short-circuited by the metal layers formed over a large surface. In the case of such known substrates, therefore, contactings between the upper side and the underside of the carrier substrate are not possible.

It is possible for an electrical connection between the electrical conductor of the carrier substrate and the functional element to be compensated with respect to the thermal expansion.

Despite the improved thermal coupling of the functional structures of the functional element to the underside of the power module, temperature differences may occur within the power module. Differing materials in the power module generally have differing coefficients of thermal expansion, for which reason formation of temperature gradients in the module, without further measures, results in thermally induced mechanical stresses.

The compensation of differing thermal expansions consequently results in a reduction of the mechanical stresses, and consequently in a reduction of the mechanical loads on the electrical connection points between the carrier substrate and the functional element. Besides the reduced susceptibility to defects that results from the reduction of the thermal load of the functional element, and the reduction of the susceptibility to defects that results from protection against unwanted electrical pulses, the susceptibility to defects is therefore also reduced in respect of mechanical damage to the connection points between the substrate and the functional unit.

A preferred possibility for compensating the thermal expansions consists in using the same material for electrically conducting structures on the underside of the functional element and for electrically conducting structures on the upper side of the recess.

Preferred in this case, in particular, are materials that exhibit an isotropic thermal expansion behavior, and whose tensor of the coefficient of expansion has only diagonal elements that are other than zero and equal.

It is thus possible to use only copper or only silver on the underside of the functional element and on the upper side of the carrier substrate in the recess, and for connections, e.g., bump connections, between them.

It is also possible for the power module to comprise a temperature buffer. The functional element may be spaced apart in the vertical direction from the underside of the recess, which is formed there by the local upper side of the carrier substrate, or in the horizontal direction from lateral walls of the recess. Correspondingly, there exists a vertical gap next to the functional element, or a horizontal gap between the functional element and the “base” of the recess. This gap may be filled by the material of the temperature buffer. In the horizontal direction, the functional element may have a first coefficient. The carrier substrate, in the horizontal direction, may have a second temperature expansion coefficient, which is different from the first coefficient. Upon a change in temperature, the widths of the functional element and of the recess change to differing extents. Correspondingly, the gap becomes larger or smaller. The temperature buffer preferably has a temperature expansion coefficient that corresponds substantially to the—easily computationally ascertainable—“temperature expansion coefficient” of the gap. This means that, owing to the temperature buffer, for each temperature and in the case of temperature changes, there is a positive-engagement connection between the carrier substrate and the functional element, as a result of which the mechanical stability of the power module is increased. In particular, it is possible for the temperature expansion coefficient of the gap and that of the temperature buffer to differ by 5 ppm/K or less.

It is possible for the power module to comprise a driver circuit for driving the functional element. The driver circuit in this case may be arranged on or over the carrier substrate, or be integrated in the carrier substrate. The driver circuit may also be arranged on or over the functional element, or be integrated in the functional element.

If the power module has more than one functional element, a single driver circuit may drive several, or all, functional elements. Alternatively, it is also possible that each functional element is provided with its own driver circuit, or that there are different groups of functional elements and one driver circuit is provided for each group of functional elements.

It is possible for the power module to comprise a sensor. The sensor may be arranged on or over the carrier substrate, or be integrated in the carrier substrate. It is also possible for the sensor to be arranged on or over the functional element, or to be integrated in the functional element.

The sensor may be, in particular, a temperature sensor that constantly observes a current temperature level of the functional element, carrier substrate or entire power module, and forwards temperature values to the driver circuit.

The driver circuit may have an integrated circuit logic, which, by closed-loop or open-loop control, controls the activity of the functional element or of the multiplicity of functional elements in dependence on external control signals and in dependence on the measured value of the sensor.

It is possible for the power module to have a multiplicity of functional elements. The functional elements may be positioned together in a regular arrangement in the recess or in separate recesses. The functional elements in this case may be positioned, in particular, in rows and columns, i.e., in a matrix arrangement.

Correspondingly, it is possible for the power module to be a LED matrix module.

It is possible for one or more dielectric layers of the carrier substrate to comprise a ceramic material, or to be composed of a ceramic material, or to comprise an organic material, or to be composed of an organic material, or to comprise a glass, or to be composed of a glass.

As a ceramic material, for example, AlN and Al₂O₃ are possible. A resin is possible as an organic material. As a glass, ordinary glasses are possible.

It is also possible for the dielectric material in the carrier substrate to be a standard material for printed circuit boards, e.g., multilayer printed circuit boards, e.g., FR4.

It is possible for the power module to be used as a lamp, e.g., as a main beam, dipped beam or daytime running light, or as a direction indicator (flashing indicator).

### BRIEF DESCRIPTION OF THE DRAWINGS

Functioning principles of the power module and selected details of possible embodiments are explained in greater detail in the following, on the basis of the schematic figures.

There are shown

FIG. 1 shows the position of a functional element in a recess in the carrier substrate;

FIG. 2 shows a functional element comprising a functional structure and a thermal bridge;

FIG. 3 shows an embodiment of the thermal bridge having a multilayer structure;

FIG. 4 shows the arrangement of the functional element in a recess that extends fully through the carrier substrate;

FIG. 5 shows a top view of a matrix arrangement of functional elements;

FIG. 6 shows an arrangement of a plurality of functional elements in a single recess;

FIG. 7 shows a functional element having a plurality of functional structures, arranged next to each other, and an ESD protection in the thermal bridge;

FIG. 8 shows a power module comprising a sensor; and

FIG. 9 shows a power module comprising a driver circuit.

### DETAILED DESCRIPTION OF ILLUSTRATIVE EMBODIMENTS

FIG. 1 shows the basic structure of a power module LM, having a carrier substrate TS that comprises a plurality of layers. These include, in particular, dielectric layers DL of an insulating material, and metallization layers ML, in which electrical structures can be formed. In the carrier substrate TS there is a recess AN, in which the functional element FE is arranged. The recess shown in FIG. 1 has the shape of a so-called blind hole, i.e., the recess has a base. The functional element FE sits on the base of the recess. In the case of a power module LM having a recess AN that is open only in one direction, the side toward which the recess AN is open is the upper side OS. The opposite side is the underside US.

The functional element FE is interconnected, via an electrical contact EK, with the electrical conductor EL, e.g., formed in a metallization layer.

Heat that is formed in the functional element FE, in particular on the upper side of the functional element FE, penetrates the functional element FE with little resistance. In order that this heat can be removed, via the underside US of the power module LM, to an external environment, in the case of a blind hole, as a recess AN, a lesser quantity of carrier substrate material has to be overcome than if the functional element FE were arranged, not in a recess, but on the upper side OS of the carrier substrate.

Correspondingly, it is also preferred if the local thickness of the carrier substrate TS in the region of the recess AN is less than locally in a region without a recess.

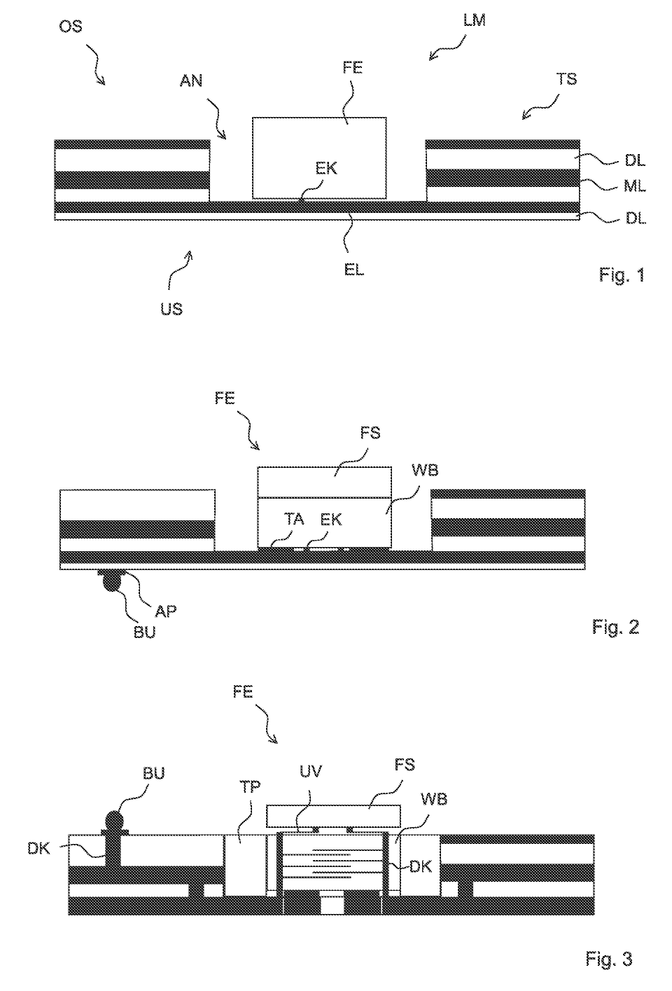

FIG. 2 shows an arrangement in which the functional element FE has two regions, arranged one above the other. The upper region is formed by a portion having functional structures FS, which realize, for example, an electrical or electronic or optical function. Arranged beneath it is the thermal bridge WB, which conducts heat, generated in the upper portion, to the underside of the functional element FE, and thus to the underside of the power module.

In order to simplify transfer of the heat to the underside of the power module, the thermal bridge WB is connected to the base of the recess via a thermal coupling TA. The thermal coupling TA, e.g., formed by conductive paste or a metallization, reduces the thermal resistance. The thermal coupling TA in this case preferably comprises materials having low thermal resistance, e.g., copper or silver.

Terminal connection pads AP, which are formed, for example, by a UBM (UBM=under-bump metallization), may be provided on the underside of the power module. Via such a terminal connection pad, the power module can be connected to, and interconnected with, an external environment.

FIG. 3 shows details of a power module in which the thermal bridge WB has a multilayer structure. Arranged therein, above one another, are dielectric layers and metallization layers. Such a structure conducts heat well if the material if the dielectric material is selected accordingly. In addition to removing heat, such a thermal bridge WB may provide an electrical or electrical function. It is thus possible for electrodes to be formed in the metallization layers. The electrodes are separated from each other in the vertical direction by dielectric material. Differing terminal connections are assigned to electrodes that are adjacent in the vertical direction. If the dielectric material is a varistor ceramic, the two differing terminal connections are insulated from each other with respect to a low voltage. If a high voltage, e.g., an ESD pulse is present at the two differing terminal connections, the varistor ceramic exhibits a reduced electrical resistance and the ESD pulse can be diverted to a reference potential.

The thermal bridge WB has vertical through-platings DK (vias), via which the functional structures FS on the upper side of the functional element are interconnected with structured metallizations of the carrier substrate.

In the multilayer carrier substrate, also, there are through-platings DK, which interconnect the circuit elements or conductors of differing metallizations layers. Through-platings DK make it possible for all external terminal connections of the power module to be arranged on one side of the power module, facilitating integration into an external circuit environment.

The multilayer structure of the functional element FE has an additional external wiring UV, in order to simplify the electrical contacting of the functional structures to terminal contacts on the thermal bridge WB.

In the horizontal direction, the functional element FE is spaced apart from the lateral walls of the recess. This volume is filled by material of a temperature buffer TP, which has a temperature expansion coefficient selected such that the increase and decrease of the buffer TP is equal to the increase and decrease of the width of the gap.

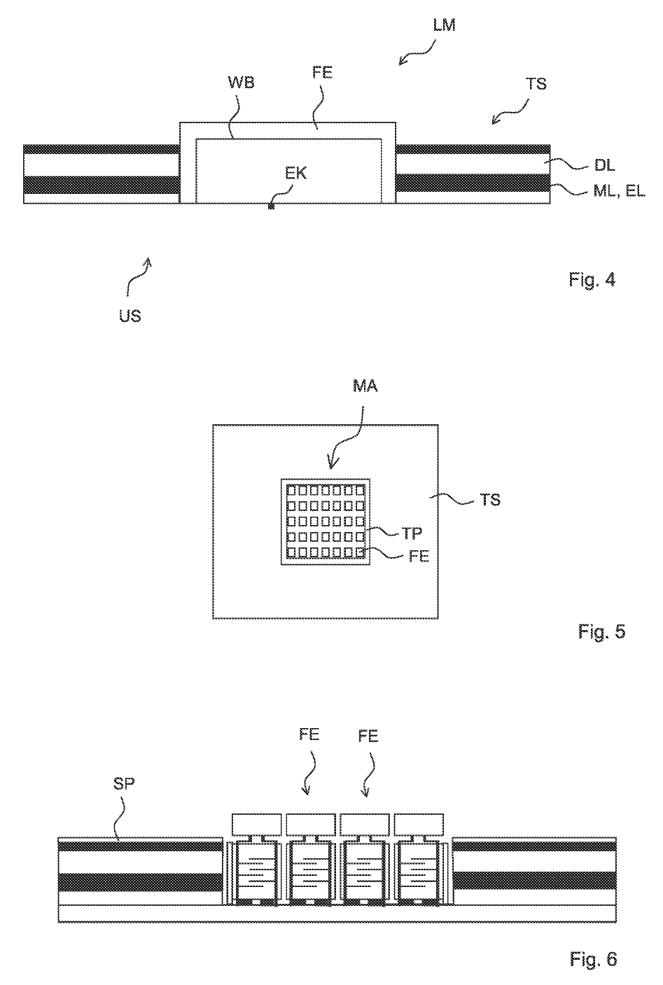

FIG. 4 shows a form of a power module in which the recess extends fully through the carrier substrate, and in the entire region of the base. In order to reduce maximally the overall height of the power module, the functional element is fully embedded in the carrier substrate. In order to simplify integration into an external environment, and in particular to simplify the downward emission of heat, the underside of the functional element FE, in particular of its thermal bridge WB, and the underside US of the carrier substrate are in flush alignment, such that a substantially smooth underside of the power module as a whole is obtained.

Electrical contacts on the underside of the functional element may then project out of the underside of the power module. Alternatively, it is also possible for the functional element FE to be embedded in the carrier substrate only to such an extent that the underside of the carrier substrate is flush with the underside of the electrical contacts EK.

FIG. 5 shows a top view of a matrix arrangement MA, in which a multiplicity of functional elements FE is aligned in rows and columns.

FIG. 6 illustrates the possibility of providing a single recess, and arranging a multiplicity of functional elements FE therein. Each of the functional elements FE may comprise a thermal bridge having a multilayer structure, and functional structures above the thermal bridge.

The uppermost layer of the carrier substrate may be a mirror SP that reflects light. If the functional structures constitute light sources, the total quantity of radiated light of the power module is increased if less light is absorbed by the otherwise passive upper side of the carrier substrate.

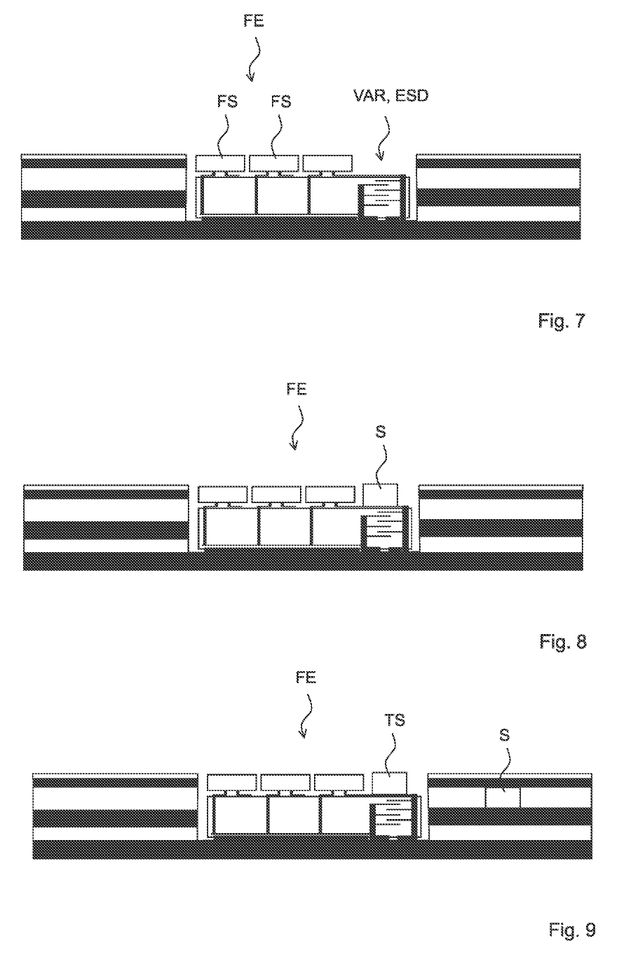

FIG. 7 shows the possibility of providing a plurality of functional structures FS in a single functional element FE. The thermal bridge of the functional element FE has a multilayer structure comprising varistor material, and provides an ESD protective function.

FIG. 8 shows the possibility of arranging a sensor directly on the upper side of the functional element FE. Alternatively, the sensor may also be arranged in the multilayer structure of the functional element or in the carrier substrate.

FIG. 9 thus shows the possibility of arranging the sensor S inside the multilayer structure of the carrier substrate. Arranged on the functional element FE, on the other hand, is a driver circuit TSG for driving the functional structures and controlling their mode of operation by open-loop or closed-loop control. The driver circuit TSG in this case may also include electrical or electronic power components. In this case, arrangement on the thermal bridge is preferred.

The power module and the use of the power module are not limited by the technical features described and the details shown. Power modules having additional circuit elements, additional terminal connections and additional recesses are also included within the scope of protection.

1-18. (canceled)

19. A power module comprising:
a carrier substrate having a dielectric layer, a metallization layer and a recess; and
an electrical functional element,
wherein the metallization layer comprises a structured electrical conductor,
wherein the functional element is interconnected with the electrical conductor,
wherein the functional element is arranged in the recess, and
wherein the functional element comprises a thermal bridge that has a greater thermal conductivity than the carrier substrate.

20. The power module according to claim 19, wherein the thermal bridge is configured to remove heat, generated during operation, to an underside of the power module.

21. The power module according to claim 19, wherein the thermal bridge comprises a ceramic material.

22. The power module according to claim 19, wherein the thermal bridge comprises a material selected from the group consisting of ZnO—Bi, ZnO—Pr, AlN, Al₂O₃, and SiC.

23. The power module according to claim 19, wherein the thermal bridge comprises a multilayer structure having a dielectric layer and a metallization layer.

24. The power module according to claim 19, wherein the thermal bridge comprises an ESD protective element.

25. The power module according to claim 19, wherein the thermal bridge comprises a varistor.

26. The power module according to claim 19, wherein the functional element comprises functional structures configured to emit light.

27. The power module according to claim 19, wherein the carrier substrate and/or the functional element have/has vertical through-platings.

28. The power module according to claim 19, wherein an electrical connection between the electrical conductor and the functional element is compensated with respect to a thermal expansion.

29. The power module according to claim 28, wherein electrically conducting structures on an underside of the functional element and on an upper side of the recess comprise the same material.

30. The power module according to claim 19, further comprising a gap filled with a temperature buffer that has the same temperature expansion coefficient as the gap.

31. The power module according to claim 19, further comprising a driver circuit arranged on or in the carrier substrate, or on or in the functional element, wherein the driver circuit is configured to drive the functional element.

32. The power module according to claim 19, further comprising a sensor arranged on or in the carrier substrate, or on or in the functional element.

33. The power module according to claim 19, wherein the power module comprises a plurality of functional elements which are positioned in a regular arrangement in the recess.

34. The power module according to claim 19, wherein the power module is an LED matrix module.

35. The power module according to claim 19, wherein the dielectric layer comprises a ceramic material or is composed of a ceramic material, or comprises an organic material or is composed of an organic material, or comprises glass or is composed of glass.

36. A vehicle comprising:
a lamp comprising the power module according to claim 19.

37. A power module comprising:
a carrier substrate having a dielectric layer, a metallization layer and a recess; and
an electrical functional element,
wherein the metallization layer comprises a structured electrical conductor,
wherein the functional element is interconnected with the electrical conductor,
wherein the functional element is arranged in the recess,
wherein the functional element comprises a thermal bridge, which has a greater thermal conductivity than the carrier substrate,
wherein the thermal bridge comprises or a material selected from the group consisting of ZnO—Bi, ZnO—Pr, AlN, Al₂O₃, and SiC, and
wherein the thermal bridge comprises an ESD protective element and/or a varistor.

38. A power module comprising:
a carrier substrate having a dielectric layer, a metallization layer and a recess;
an electrical functional element;
a driver circuit configured to drive the functional element, wherein the driver circuit is arranged on or in the carrier substrate, or on or in the functional element; and
a sensor arranged on or in the carrier substrate, or on or in the functional element,
wherein the metallization layer comprises a structured electrical conductor,
wherein the functional element is interconnected with the electrical conductor,
wherein the functional element is arranged in the recess, and
wherein the functional element comprises a thermal bridge, the thermal bridge having a greater thermal conductivity than the carrier substrate.
